(19) United States
(12) Patent Application Publication
(10) Pub. No.: US 2024/0324374 A1
(43) Pub. Date: Sep. 26, 2024

(54) DISPLAY PANEL

(71) Applicant: Samsung Display Co., Ltd., Yongin-si (KR)

(72) Inventors: Youngsoo Yoon, Yongin-si (KR); Taehyoung No, Yongin-si (KR); Bongwon Lee, Yongin-si (KR); Haeyeon Lee, Yongin-si (KR)

(21) Appl. No.: 18/493,707

(22) Filed: Oct. 24, 2023

(30) Foreign Application Priority Data
Mar. 24, 2023 (KR) 10-2023-0039105
Jun. 13, 2023 (KR) 10-2023-0075545

(51) Int. Cl. H10K 59/131; G09G 3/3266; H10K 59/121

(52) U.S. Cl. CPC H10K 59/1315; G09G 3/3266; H10K 59/1213

(57) ABSTRACT

A display panel includes: a substrate comprising a display area and a peripheral area; first signal lines on the substrate extending in a first direction; data lines on the substrate extending in a second direction crossing the first direction; pixel circuits arranged in a matrix along the first direction and the second direction and display elements respectively connected to the pixel circuits, the pixel circuits and the display elements being arranged in the display area; a first internal circuit unit comprising first internal circuits arranged along the first direction in the peripheral area; connection lines in the peripheral area to connect each of the first internal circuits to each of the first signal lines; and a common voltage supply line in the peripheral area between the first internal circuit unit and an edge of the substrate, wherein at least some of the connection lines overlap the common voltage supply line.

### CROSS-REFERENCE TO RELATED APPLICATIONS

The present application claims priority to and the benefit of Korean Patent Application No. 10-2023-0039105, filed on Mar. 24, 2023, and Korean Patent Application No. 10-2023-0075545, filed on Jun. 13, 2023, in the Korean Intellectual Property Office, the entire content of each of which in is incorporated by reference.

### BACKGROUND

### 1. Field

Aspects of one or more embodiments relate to a display panel.

### 2. Description of Related Art

A display apparatus is an apparatus that visually displays data. Such a display apparatus includes a substrate divided into a display area and a peripheral area. In the display area, scan lines and data lines are formed to be insulated from each other, and the scan lines and the data lines cross each other, thereby defining a plurality of pixel areas in the display area. In addition, the display area includes a thin-film transistor and a pixel electrode electrically connected to the thin-film transistor, the thin-film transistor and the pixel electrode corresponding to each of the pixel areas. In addition, the display area includes an opposite electrode commonly provided in the pixel areas. The peripheral area may include various lines configured to transmit an electronic signal to the display area, an internal circuit unit including a scan driving circuit and an emission control driving circuit, a data driving unit, a controller, and the like.

The usage of such a display apparatus has diversified. Also, as thicknesses and weights of display apparatuses have decreased, the range of applications of display apparatuses has increased. As display apparatuses are used in various ways, methods of using the peripheral area in various ways in designing the form of the display apparatus are being explored.

The above information disclosed in this Background section is only for enhancement of understanding of the background and therefore the information discussed in this Background section does not necessarily constitute prior art.

### SUMMARY

Aspects of one or more embodiments relate to a display panel, and for example, to a display panel with an internal circuit unit on top of the display panel, and a display apparatus including the display panel.

Aspects of one or more embodiments include a display apparatus for minimizing or reducing a dead space and implementing a high-quality image. However, the one or more embodiments are only examples, and the scope of embodiments according to the present disclosure is not limited thereto.

Additional aspects will be set forth in part in the description which follows and, in part, will be apparent from the description, or may be learned by practice of the presented embodiments of the disclosure.

According to one or more embodiments, a display panel includes a substrate including a display area and a peripheral area surrounding the display area, first signal lines on the substrate and extending in a first direction, data lines on the substrate and extending in a second direction crossing the first direction, pixel circuits arranged in a matrix along the first direction and the second direction and display elements respectively connected to the pixel circuits, the pixel circuits and the display elements being arranged in the display area, a first internal circuit unit including first internal circuits arranged along the first direction in the peripheral area, and connection lines arranged in the peripheral area to connect each of the first internal circuits to each of the first signal lines, wherein the first internal circuit unit includes a 1-1^{st} internal circuit unit in which the first internal circuits configured to provide signals to the pixel circuits arranged in the first to i^{th} rows are arranged in a reverse direction to the first direction, and a 1-2^{nd} internal circuit unit in which the first internal circuits configured to provide signals to the pixel circuits arranged in the i+1^{st} to n^{th} rows are arranged in the first direction.

According to some embodiments, the connection lines may include first connection lines arranged between the first internal circuit unit and the display area, and second connection lines arranged between the first internal circuit unit and an edge of the substrate.

According to some embodiments, the display panel may further include a common voltage power source line arranged in the peripheral area and surrounding at least a portion of the display area, wherein at least some of the connection lines may overlap the common voltage power source line.

According to some embodiments, the peripheral area may include a first peripheral area arranged outside a first side of the display area, a second peripheral area arranged outside a second side of the display area, and a corner peripheral area arranged outside a corner at which the first side and the second side meet, a corner internal circuit unit may be arranged in the corner peripheral area, and the corner internal circuit unit may be configured to provide a signal different from that of the first internal circuit unit to the pixel circuits.

According to some embodiments, the corner internal circuit unit may include second internal circuits configured to provide a signal different from that of the first internal circuits.

According to some embodiments, the first internal circuits may be emission control driving circuits, and the second internal circuits may be scan driving circuits.

According to some embodiments, the second internal circuits may be arranged radially according to a shape of the corner peripheral area.

According to some embodiments, some of the connection lines may be arranged between the second internal circuits.

According to some embodiments, a scan driving circuit and an emission control driving circuit may be arranged in a pair in the second peripheral area.

According to some embodiments, the second internal circuit unit is arranged in the second peripheral area, and a third connection line among the connection lines may connect the first internal circuit unit and the second internal circuit unit.

According to some embodiments, a portion of the third connection line may be arranged between the first internal circuit unit and the display area, and another portion may be arranged between the corner internal circuit unit and an edge of the substrate.

According to one or more embodiments, a display panel includes a substrate including a display area and a peripheral area surrounding the display area, first signal lines on the substrate and extending in a first direction, data lines on the substrate and extending in a second direction crossing the first direction, pixel circuits arranged in a matrix along the first direction and the second direction and display elements respectively connected to the pixel circuits, the pixel circuits and the display elements being arranged in the display area, a first internal circuit unit including first internal circuits arranged along the first direction in the peripheral area, connection lines arranged in the peripheral area to connect each of the first internal circuits to each of the first signal lines, and a common voltage supply line arranged in the peripheral area between the first internal circuit unit and an edge of the substrate, wherein at least some of the connection lines overlap the common voltage supply line.

According to some embodiments, the connection lines may include first connection lines and second connection lines, the first connection lines and the second connection lines extending from the first internal circuit unit in different directions from each other.

According to some embodiments, the first connection lines may be arranged between the first internal circuit unit and the display area, and second connection lines may be arranged between the first internal circuit unit and the edge of the substrate.

According to some embodiments, the peripheral area may include a first peripheral area arranged outside a first side of the display area, a second peripheral area arranged outside a second side of the display area, and a corner peripheral area arranged outside a corner at which the first side and the second side meet, a corner internal circuit unit may be arranged in the corner peripheral area, and the corner internal circuit unit may be configured to provide a signal different from that of the first internal circuit unit to the pixel circuits.

According to some embodiments, the corner internal circuit unit may include second internal circuits.

According to some embodiments, the first internal circuits may be emission control driving circuits, and the second internal circuits may be scan driving circuits.

According to some embodiments, the second internal circuits may be arranged radially according to a shape of the corner peripheral area.

According to some embodiments, some of the connection lines may be arranged between the second internal circuits.

According to some embodiments, the second internal circuit unit is arranged in the second peripheral area, and a third connection line among the connection lines may connect the first internal circuit unit and the second internal circuit unit.

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a plan view schematically illustrating a portion of a display apparatus according to some embodiments;

FIG. 2 is a side view schematically illustrating the display apparatus of FIG. 1 according to some embodiments;

FIG. 3 is an equivalent circuit diagram of a pixel circuit of a display apparatus and a display element connected to the pixel circuit according to some embodiments;

FIG. 4 is a schematic cross-sectional view of the display apparatus of FIG. 1 taken along the line I-I′ according to some embodiments;

FIG. 5A is a schematic plan view of a display panel corresponding to a region II of FIG. 1 according to some embodiments;

FIG. 5B is a schematic plan view of a display panel corresponding to a region II of FIG. 1 according to some embodiments;

FIG. 6 is a view showing an arrangement of internal circuits arranged in a first internal circuit unit according to some embodiments;

FIG. 7 is a schematic plan view of connection lines connecting an internal circuit unit of a peripheral area to lines of a display area according to some embodiments; and

FIG. 8 is a schematic cross-sectional view of a peripheral area of a display panel taken along the line III-III′ of FIG. 7 according to some embodiments.

### DETAILED DESCRIPTION

Reference will now be made in more detail to aspects of some embodiments, which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or any combination of a, b, and/or c.

Because the disclosure may have diverse modified embodiments, aspects of some embodiments are illustrated in the drawings and are described in the detailed description. An effect and a characteristic of the disclosure, and a method of accomplishing these will be apparent when referring to embodiments described with reference to the drawings. The disclosure may, however, be embodied in many different forms and should not be construed as limited to the embodiments set forth herein.

One or more embodiments of the disclosure will be described below in more detail with reference to the accompanying drawings. Those elements that are the same or are in correspondence are rendered the same reference numeral regardless of the figure number, and redundant descriptions thereof are omitted.

It will be understood that although terms such as “first” and “second” may be used herein to describe various elements, these elements should not be limited by these terms and these terms are only used to distinguish one element from another element.

As used herein, the singular forms “a,” “an,” and “the” are intended to include the plural forms as well, unless the context clearly indicates otherwise.

Also, it will be understood that the terms “comprise,” “include,” and “have” used herein specify the presence of stated features or elements, but do not preclude the presence or addition of one or more other features or elements.

It will be understood that when a layer, region, or element is referred to as being “on” another layer, region, or element, it may be “directly on” the other layer, region, or element or may be “indirectly on” the other layer, region, or element with one or more intervening layers, regions, or elements therebetween.

In the drawings, for convenience of description, sizes of components may be exaggerated or reduced. In other words, because sizes and thicknesses of elements in the drawings are arbitrarily illustrated for convenience of description, the following embodiments are not limited thereto.

It will be understood that when a layer, region, or component is referred to as being connected to another layer, region, or component, it can be directly or indirectly connected to the other layer, region, or component. That is, for example, intervening layers, regions, or components may be present. For example, when layers, areas, or elements or the like are referred to as being “electrically connected,” they may be directly electrically connected, or layers, areas or elements may be indirectly electrically connected, and an intervening layer, region, component, or the like may be present therebetween.

In the following embodiments, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

The display apparatus is an apparatus that displays an image, and may include a liquid crystal display apparatus, an organic light-emitting display apparatus, an inorganic light-emitting display apparatus (or an inorganic EL display), a micro LED display apparatus, and a quantum dot light-emitting display apparatus. For example, an emission layer of the display element included in the display apparatus may include an organic material or an inorganic material. In addition, the display apparatus may have an emission layer and a quantum dot layer in a path of light emitted from the emission layer.

Hereinafter, although an organic light-emitting display apparatus is described as a display apparatus according to some embodiments, the display apparatus of the disclosure is not limited thereto, and various display apparatuses may be used.

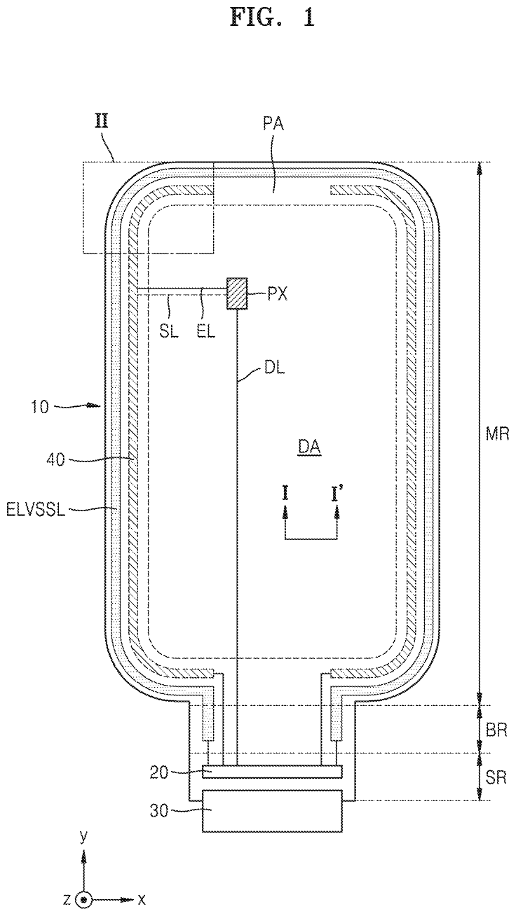

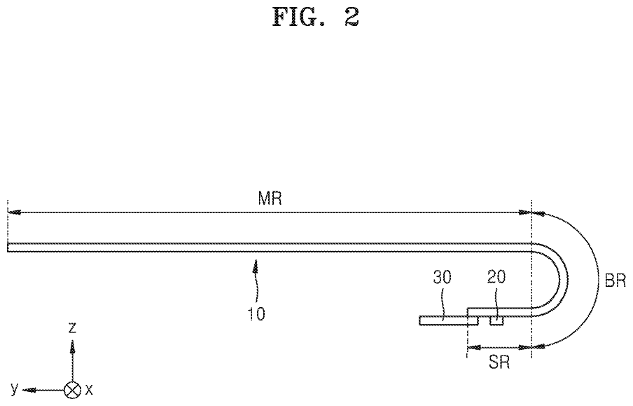

FIG. 1 is a plan view schematically illustrating a portion of a display apparatus, according to some embodiments. FIG. 2 is a side view schematically illustrating the display apparatus of FIG. 1. A portion of the display apparatus according to some embodiments may be bent as shown in FIG. 2. However, for convenience of illustration and description, FIG. 1 shows that the display apparatus is not bent.

As shown in FIGS. 1 and 2, the display apparatus according to some embodiments includes a display panel 10. The display apparatus may be any display apparatus that includes the display panel 10. For example, the display apparatus may include various electronic products or devices, such as smartphones, tablet computers, laptop computers, smart watches, televisions, advertisement boards, and the like.

The display panel 10 may include a display area DA and a peripheral area PA outside (e.g., in a periphery or outside a footprint of) the display area DA. The display area DA may include a portion a which images are displayed, and a plurality of pixels may be arranged in the display area DA. When viewed in a direction approximately perpendicular or normal to a display surface of the display panel 10 (e.g., in a plan view), the display panel 10 may have various shapes, such as a circle, an ellipse, a polygon, or a specific figure or shape. In FIG. 1, the display area DA has a substantially rectangular shape with round corners.

The peripheral area PA may be arranged outside the display area DA. The width (in the x-axis direction) of a portion of the second peripheral area PA2 may be less than the width (in the x-axis direction) of the display area DA. Through this structure, at least a portion of the peripheral area PA may be relatively easily bent as described below.

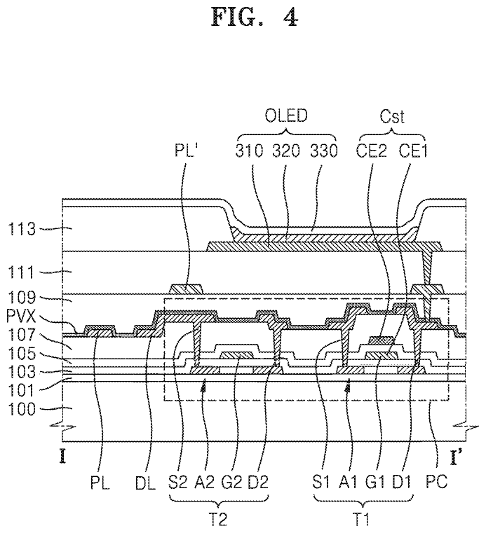

As the display panel 10 includes a substrate 100 (see FIG. 4), the substrate 100 may include the display area DA and the peripheral area PA. Hereinafter, for convenience of description, the substrate 100 will be described as including the display area DA and the peripheral area PA.

The display panel 10 may include a main area MR, a bending area BR outside the main area MR, and a sub-area SR located opposite to the main area MR with the bending area BR therebetween. In the bending area BR, the display panel 10 is bent as shown in FIG. 2, so that at least a portion of the sub-area SR may overlap the main area MR when viewed in a z-axis direction (e.g., in a plan view). However, embodiments according to the present disclosure are not limited to a bendable display apparatus and may be applicable to a display apparatus that is not bendable. The sub-area SR may be a non-display area as described below. By bending the display panel 10 in the bending area BR, when the display apparatus is viewed from the front (in the −z direction), the non-display area may not be visible, and even in a case in which the non-display area is visible, the visible area of the non-display area may be relatively reduced.

A driving chip 20 may be arranged in the sub-area SR of the display panel 10. The driving chip 20 may include an integrated circuit configured to drive the display panel 10. The integrated circuit may include a data driving integrated circuit configured to generate a data signal, but the disclosure is not limited thereto.

The driving chip 20 may be mounted in the sub-area SR of the display panel 10. The driving chip 20 is mounted on the same surface as a display surface of the display area DA, but when the display panel 10 is bent in the bending area BR, as described above, the driving chip 20 may be located on the rear surface of the main area MR.

A printed circuit board 30 or the like may be attached to an end of the sub area SR of the display panel 10. The printed circuit board 30 or the like may be electrically connected to the driving chip 20 or the like through a pad on the substrate.

A plurality of (sub) pixels PX are located in the display area DA. Each of the pixels PX may include a display element, such as an organic light-emitting diode OLED. The pixel PX may emit, for example, red light, green light, blue light, or white light.

The pixels PX may be electrically connected to outer circuits arranged in the peripheral area PA. An internal circuit unit 40, a common voltage supply line ELVSSL, a driving voltage supply line, and a terminal may be arranged in the peripheral area PA.

The internal circuit unit 40 may surround at least a portion of the display area DA in the peripheral area PA. The internal circuit unit 40 may be arranged in correspondence with the right and/or left side of the display area DA. At least a portion of the internal circuit unit 40 may be arranged at the upper side and/or the lower side of the display area DA.

The internal circuit unit 40 may include a scan driving circuit and an emission control driving circuit. The scan driving circuit 11 may provide a scan signal to the pixel PX through a scan line SL. The emission control driving circuit may provide an emission control signal to the pixel PX through an emission control line EL.

The common voltage supply line ELVSSL may be arranged outside the internal circuit unit 40 and may surround at least a portion of the display area DA. The display area DA may be partially surrounded by the common voltage supply line ELVSSL in the peripheral area PA. The common voltage supply line ELVSSL may extend along the remaining sides of the display area DA excluding any one side of the display area DA. The common voltage supply line ELVSSL may surround the right side, the upper side, and the left side of the display area DA. The internal circuit unit 40 may be arranged between the common voltage supply line ELVSSL and the display area DA.

The terminal located in the peripheral area PA may be exposed without being covered by an insulating layer and may be electrically connected to the printed circuit board 30. A terminal of the printed circuit board 30 may be electrically connected to a terminal of the display panel 10.

The printed circuit board 30 is configured to transmit a signal or power from a controller to the display panel 10. Control signals generated by the controller may be transmitted to driving circuits through the printed circuit board 30. Also, the controller may provide a driving power supply voltage ELVDD (driving voltage) to the driving voltage supply line, and may provide a common power supply voltage ELVSS to the common voltage supply line. The controller may generate a data signal, and the generated data signal may be transmitted to the pixel through the driving chip 20 and the data line DL.

According to some embodiments, a portion of the internal circuit unit 40 is arranged on the upper side of the display area DA to reduce the size of the peripheral area PA.

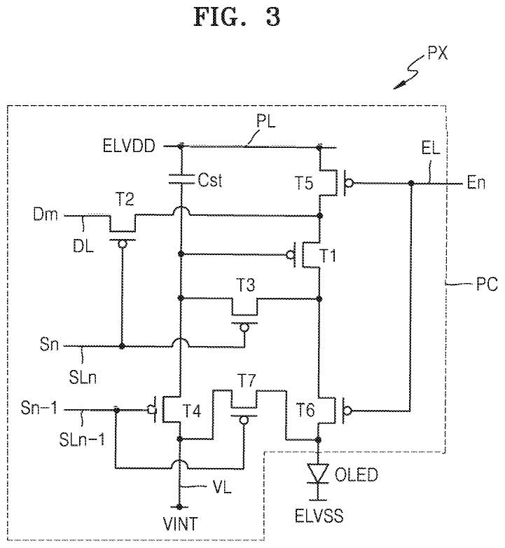

FIG. 3 is an equivalent circuit diagram of a pixel circuit of the display apparatus according to some embodiments and a display element connected to the pixel circuit.

Referring to FIG. 3, a pixel circuit PC may include driving and switching thin-film transistors T1 and T2, a compensation thin-film transistor T3, a first initialization thin-film transistor T4, a first emission control thin-film transistor T5, a second emission control thin-film transistor T6, and a second initialization thin-film transistor T7.

In FIG. 3, a case in which each pixel circuit PC is provided with signal lines SLn, SLn−1, EL, and DL, an initialization voltage line VL, and a driving voltage line PL is illustrated, but the disclosure is not limited thereto. According to some embodiments, at least one of the signal lines SLn, SLn−1, EL, or DL, and/or the initialization voltage line VL may be shared by neighboring pixels.

A drain electrode of the driving thin-film transistor T1 may be electrically connected to the organic light-emitting diode OLED via the second emission control thin-film transistor T6. The driving thin-film transistor T1 may be configured to receive a data signal Dm and supply the driving current to the organic light-emitting diode OLED according to a switching operation of the switching thin-film transistor T2.

A gate electrode of the switching thin-film transistor T2 is connected to a scan line SL, and a source electrode of the switching thin-film transistor T2 is connected to the data line DL. The drain electrode of the switching thin-film transistor T2 may be connected to the source electrode of the driving thin-film transistor T1 and may be connected to the driving voltage line PL via the first emission control thin-film transistor T5.

The switching thin-film transistor T2 may be turned on in response to a first scan signal Sn received through the scan line SLn to perform a switching operation of transmitting the data signal Dm transmitted to the data line DL to the source electrode of the driving thin-film transistor T1.

A gate electrode of the compensation thin-film transistor T3 may be connected to the scan line SLn. A source electrode of the compensation thin-film transistor T3 may be connected to the drain electrode of the driving thin-film transistor T1 and may be connected to a pixel electrode of the organic light-emitting diode OLED via the second emission control thin-film transistor T6. A drain electrode of the compensation thin-film transistor T3 may be connected to one of the electrodes of the storage capacitor Cst, the source electrode of the first initialization thin-film transistor T4, and the gate electrode of the driving thin-film transistor T1. The compensation thin-film transistor T3 may turned on in response to the first scan signal Sn received through the scan line SL to connect the gate electrode and the drain electrode of the driving thin-film transistor T1 to each other for a diode-connection of the driving thin-film transistor T1.

The gate electrode of the first initialization thin-film transistor T4 may be connected to the previous scan line SLn−1. The drain electrode of the first initialization thin-film transistor T4 may be connected to the initialization voltage line VL. The source electrode of the first initialization thin-film transistor T4 may be connected to one of the electrodes of the storage capacitor Cst, the drain electrode of the compensation thin-film transistor T3, and the gate electrode of the driving thin-film transistor T1. The first initialization thin-film transistor T4 may be turned on in response to the second scan signal Sn−1 received through the previous scan line SLn−1 and perform an initialization operation of transmitting an initialization voltage VINT to the gate electrode of the driving thin-film transistor T1 to initialize the voltage of the gate electrode of the driving thin-film transistor T1.

The gate electrode of the first emission control thin-film transistor T5 may be connected to the emission control line EL. The source electrode of the first emission control thin-film transistor T5 may be connected to the driving voltage line PL. The drain electrode of the first emission control thin-film transistor T5 may be connected to the source electrode of the driving thin-film transistor T1 and the drain electrode of the switching thin-film transistor T2.

The gate electrode of the second emission control thin-film transistor T6 may be connected to the emission control line EL. The source electrode of the second emission control thin-film transistor T6 may be connected to the drain electrode of the driving thin-film transistor T1 and the source electrode of the compensation thin-film transistor T3. The drain electrode of the second emission control thin-film transistor T6 may be electrically connected to the pixel electrode of the organic light-emitting diode OLED. The first emission control thin-film transistor T5 and the second emission control thin-film transistor T6 may be turned on at the same time in response to the emission control signal En received through the emission control line EL such that a first power supply voltage ELVDD is transmitted to the organic light-emitting diode OLED and a driving current flows to the organic light-emitting diode OLED.

The gate electrode of the second initialization thin-film transistor T7 may be connected to the previous scan line SLn−1. The source electrode of the second initialization thin-film transistor T7 may be connected to the pixel electrode of the organic light-emitting diode OLED. The drain electrode of the second initialization thin-film transistor T7 may be connected to the initialization voltage line VL. The second initialization thin-film transistor T7 may be turned on in response to the second scan signal Sn−1 received through the previous scan line SLn−1, so that the pixel electrode of the organic light-emitting diode OLED is initialized.

FIG. 3 illustrates a case in which the first initialization thin-film transistor T4 and the second initialization thin-film transistor T7 are connected to the previous scan line SLn−1, but embodiments according to the present disclosure are not limited thereto. According to some embodiments, the first initialization thin-film transistor T4 may be connected to the previous scan line SLn−1 so as to be driven in response to the second scan signal Sn−1, and the second initialization thin-film transistor T7 may be connected to a separate signal line (e.g., the previous scan line) so as to be driven in response to a signal transmitted to the scan line.

The other electrode of the storage capacitor Cst may be connected to the driving voltage line PL. One of the electrodes of the storage capacitor CST may be connected to the gate electrode of the driving thin-film transistor T1, the drain electrode of the compensation thin-film transistor T3, and the source electrode of the first initialization thin-film transistor T4.

The second power voltage ELVSS (or the common power supply voltage) is supplied to the opposite electrode (e.g., the cathode) of the organic light-emitting diode OLED. The organic light-emitting diode OLED receives a driving current from the driving thin-film transistor T1 and emits light.

The pixel circuit PC is not limited to the number and circuit design of the thin-film transistor and the storage capacitor, and the number and circuit design may be variously modified. According to some embodiments, the pixel circuit PC may include additional components or fewer components without departing from the spirit and scope of embodiments according to the present disclosure.

FIG. 4 is a schematic cross-sectional view of a lamination structure of a display apparatus according to some embodiments, the view taken along the line I-I′ of FIG. 1.

Referring to FIG. 4, the pixel circuit PC including the thin-film transistors T1 and T2 and the storage capacitor Cst, and the organic light-emitting diode OLED, which is a display element connected to the pixel circuit PC, may be located on the substrate 100.

The substrate 100 may include a variety of materials, such as glass materials, or plastic materials such as polyethylen terephthalate (PET), polyethylen naphthalate (PEN), polyimide, etc. If the substrate 100 is formed of a plastic material, the flexibility thereof may be relatively improved more than that of the substrate formed of a glass material. Silicon oxide (SiOx) and/or a buffer layer 101 including silicon nitride (SiNx) may be formed on the substrate 100 to prevent or reduce instances of impurities being introduced.

The driving thin-film transistor T1 may include a driving semiconductor layer A1 and a driving gate electrode G1, and the switching thin-film transistor T2 may include a switching semiconductor layer A2 and a switching gate electrode G2. A first gate insulating layer 103 is arranged between the driving semiconductor layer A1 and the driving gate electrode G1, and between the switching semiconductor layer A2 and the switching gate electrode G2. The first gate insulating layer 103 may include inorganic insulating materials such as SiOx, SiNx, silicon oxynitride (SiON), and the like.

The driving semiconductor layer A1 and the switching semiconductor layer A2 may include amorphous silicon or poly silicon. According to some embodiments, the semiconductor layers A1 and A2 may include an oxide of at least one material selected from the group consisting of indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). The driving semiconductor layer A1 includes a driving channel area that is not doped with impurities and overlaps the driving gate electrode G1 and a driving source area and driving drain area that are doped with impurities on both sides of the driving channel area. The driving source electrode S1 and the driving drain electrode D1 may be connected to the driving source area and the driving drain area, respectively. The driving semiconductor layer A1 and the switching semiconductor layer A2 may include a single layer or multiple layers.

The switching semiconductor layer A2 may include a switching channel area that overlaps the switching gate electrode G2 and is not doped with impurities, and a switching source area and a switching drain area that are doped with impurities on both sides of the switching channel area. The switching source area and the switching drain area may be connected to the switching source electrode S2 and the switching drain electrode D2, respectively.

The driving and switching gate electrodes G1 and G2 may include molybdenum (Mo), aluminum (Al), copper (Cu), titanium (Ti), etc., and may include a single layer or multiple layers. For example, the driving and switching gate electrodes G1 and G2 may be a single layer of Mo.

The source electrodes S1 and S2 and the drain electrodes D1 and D2 may include a conductive material including Mo, Al, Cu, Ti, etc. and may have a multi-layer or single-layer structure including the material described above. For example, the source electrodes S1 and S2 and the drain electrodes D1 and D2 may have a multi-layer structure of Ti/Al/Ti.

In some embodiments, the storage capacitor Cst may overlap the driving thin-film transistor T1. In this case, the area of the storage capacitor Cst and the driving thin-film transistor T1 may be increased, and a high-quality image may be provided. For example, the driving gate electrode G1 may include a first storage capacitor plate CE1 of the storage capacitor Cst. The second storage capacitor plate CE2 may overlap the first storage capacitor plate CE1 while the second gate insulating layer 105 is interposed between the second storage capacitor plate CE2 and the first storage capacitor plate CE1. The second gate insulating layer 105 may include inorganic insulating materials such as SiOx, SiNx, SiON, and the like.

The driving and switching thin-film transistors T1 and T2 and the storage capacitor Cst may be covered with an interlayer insulating layer 107. The interlayer insulating layer 107 may include inorganic insulating materials such as SiON, SiOx, and/or SiNx. The data line DL and the driving voltage line PL may be located on the interlayer insulating layer 107. The data line DL may be connected to the switching semiconductor layer A2 of the switching thin-film transistor T2 through a contact hole penetrating through the interlayer insulating layer 107. The data line DL may act as the switching source electrode S2. The driving source electrode S1, the driving drain electrode D1, the switching source electrode S2, and the switching drain electrode D2 may be located on the interlayer insulating layer 107, and may be connected to the driving semiconductor layer A1 or the switching semiconductor layer A2 through the contact hole penetrating through the interlayer insulating layer 107.

The driving voltage line PL, the data line DL, the driving source electrode S1, the driving drain electrode D1, the switching source electrode S2, and the switching drain electrode D2 may be covered by an inorganic protective layer PVX.

The inorganic protective layer PVX may include a single layer or a multiple layers of SiNx and SiOx. The inorganic protective layer PVX may cover and protect some of the wires exposed in the peripheral area. In some areas of the substrate 100 (e.g. a portion of the peripheral area), wirings and/or the conductive layer formed together in the same process as that of the data line DL or the driving voltage line PL may be exposed. The exposed portions of the wirings and/or the conductive layer may be damaged by an etchant that is used when patterning the pixel electrode 310. However, according to some embodiments, because the inorganic protective layer PVX covers at least a portion of the data line DL and the wirings formed together with the data line DL, damage to the wirings and/or the conductive layer during the patterning process of a pixel electrode 310 may be prevented or reduced. The inorganic protective layer PVX may be omitted.

The first organic insulating layer 109 and the second organic insulating layer 111, which are planarization insulating layers, may include an organic material. The organic material may include an imide-based polymer, a general purpose polymer such as polymethylmethacrylate (PMMA) or polystylene (PS), a polymer derivative having a phenol-based group, an acrylic polymer, an aryl ether polymer, an amide-based polymer, a fluorine-based polymer, a p-xylene-based polymer, a vinyl alcohol-based polymer, or a blend thereof.

An additional driving voltage line PL′ may be located on the top of the first organic insulating layer 109. The additional driving voltage line PL′ may include a single layer or multiple layers including at least one of Al, Cu, Ti, and/or an alloy thereof. According to some embodiments, the additional driving voltage line PL′ may be a three-layer film of Ti/Al/Ti. The additional driving voltage line PL′ may be connected to the driving voltage line PL through the contact hole formed in the first organic insulating layer 109, thereby reducing the resistance.

The organic light-emitting diode OLED including a pixel electrode 310, a opposite electrode 330, and an intermediate layer 320 arranged between the pixel electrode 310 and the opposite electrode 330 and including an emission layer may be located on the second organic insulating layer 111.

The pixel defining layer 113 may be arranged on the pixel electrode 310. The pixel defining layer 113 defines the emission area of the pixel by including an opening that exposes the pixel electrode 310. In addition, by increasing a distance between an edge of the pixel electrode 310 and the opposite electrode 330, instances of an arc being generated therebetween may be prevented or reduced. The pixel defining layer 113 may include an organic material such as polyimide or hexamethyldisiloxane (HMDSO).

The intermediate layer 320 may include a low molecular or polymer material.

When the intermediate layer 320 includes the low molecular material, a hole injection layer (HIL), a hole transport layer (HTL), an emission layer (EML), an electron transport layer (ETL), an electron injection layer (EIL), etc. may be stacked in a single layer or multiple layers, and may include various organic materials such as copper phthalocyanine (CuPc), N,N′-Di(naphthalene-1-yl)-N,N′-diphenyl-benzidine (NPB), tris-8-hydroxyquinoline aluminum)(Alq3), etc. These layers can be formed by vacuum deposition.

When the intermediate layer 320 includes a polymer material, the intermediate layer 320 may generally have a structure including the HTL and the EML. In this case, the HTL may include poly(3,4-ethylenedioxythiophene) (PEDOT), and the EML may include a polymer material such as a polyphenylene vinylene (PPV)-based material or a polyfluorene-based material. The structure of the intermediate layer 320 may not be limited to the above description, and may have various structures. For example, the intermediate layer 320 may include a layer that is integrally formed over a plurality of pixel electrodes 310, or may include a layer that is patterned to correspond to each of the plurality of pixel electrodes 310.

The opposite electrode 330 may be arranged over the display area DA to cover the display area DA. That is, the opposite electrode 330 may be integrally formed in the plurality of organic light-emitting diodes OLED and may correspond to the plurality of pixel electrodes 310. The opposite electrode 330 may extend to the peripheral area PA and be connected to the common voltage supply line ELVSSL (see FIG. 1).

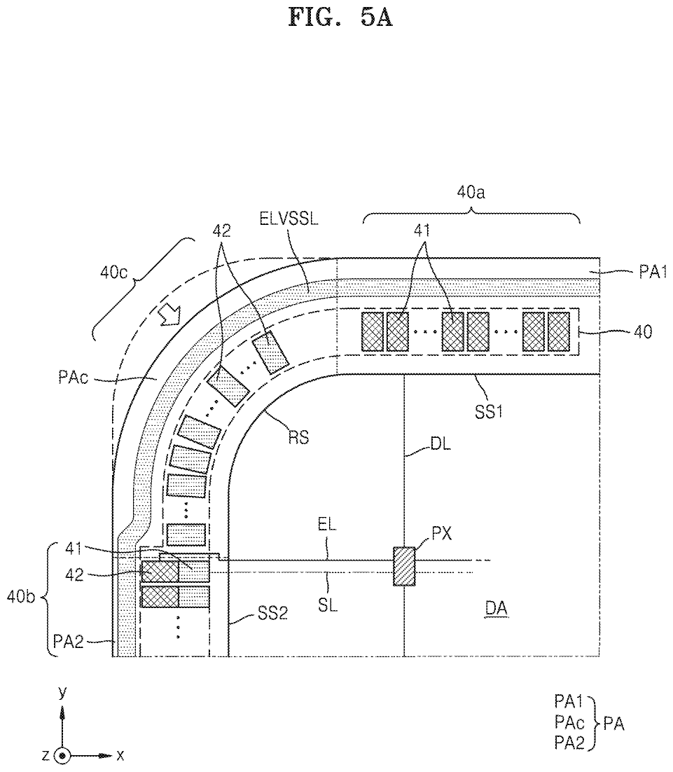

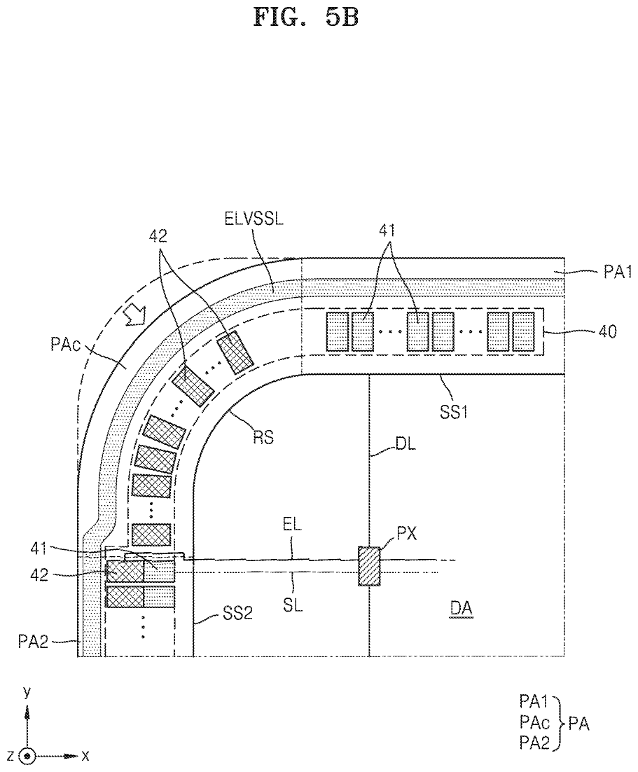

FIGS. 5A and 5B are schematic plan views of a display panel that may correspond to the region II of FIG. 1. For example, FIGS. 5A and 5B each show a portion of the upper and left side of the display panel.

Referring to FIG. 5A, an edge of the display area DA may include a first side SS1 extending in a first direction (an x direction), a second side SS2 extending in a second direction (a y direction), and a round corner RS at which the first side SS1 and the second side SS2 meet.

The peripheral area PA surrounding the display area DA may include a first peripheral area arranged on the outside of the first side SS1, a corner peripheral area PAc arranged on the outside of the round corner RS, and a second peripheral area PA2 arranged on the outside of the second side SS2.

The first peripheral area PA1 may be the peripheral area PA arranged on the upper side of the display area DA, and the second peripheral area PA2 may be the peripheral area PA arranged on the left side of the display area DA. The corner peripheral area PAc may be the peripheral area PA arranged in a corner portion between the first peripheral area PA1 and the second peripheral area PA2.

The scan line SL and the emission control line EL extending in the first direction (the x direction), and the data line DL extending in the second direction (the y direction) may be arranged in the display area DA. In the display area DA, a plurality of pixels PX emitting light through a signal transmitted by the scan line SL, the emission control line EL, and the data line DL.

The internal circuit unit 40 and the common voltage supply line ELVSSL may be arranged in the peripheral area PA. The internal circuit unit 40 may include a first internal circuit unit 40a arranged in the first peripheral area PA1, the second internal circuit unit 40b arranged in the second peripheral area PA2, and the corner internal circuit unit 40c arranged in the corner peripheral area PAc.

The first internal circuit unit 40a may include a plurality of first internal circuits 41. The first internal circuits 41 may be arranged in a line along the x direction. The first internal circuits 41 may be emission control driving circuits configured to provide an emission control signal. One first internal circuit 41 may provide the same emission control signal to the pixels arranged in the same row.

The corner internal circuit unit 40c may include a plurality of second internal circuits 42. The second internal circuits 42 may be arranged radially according to the shape of the corner peripheral area PAc. The second internal circuits 42 may be arranged in a shape of a curve. Alternatively, the second internal circuits 42 may be arranged in a shape of a staircase. The second internal circuits 42 may be scan driving circuits configured to provide a scan signal. One second internal circuit 42 may provide the same scan signal to the pixels arranged in the same row.

The second internal circuit unit 40b may include the plurality of first internal circuits 41 and the plurality of second internal circuits 42. One of the first internal circuits 41 and one of the second internal circuits 42 may be arranged in pairs. Because the first internal circuit 41 is an emission control driving circuit, and the second internal circuit 42 is a scan driving circuit, a pair of the first internal circuit 41 and the second internal circuit 42 may provide the same emission control signal and scan signal, respectively, to the pixels arranged in the same row.

According to some embodiments, because only one of the scan driving circuit and the emission control driving circuit is arranged in the corner internal circuit unit 40c and the other is arranged in the first internal circuit unit 40a, the space of the corner peripheral area PAc may be reduced. That is, the edge of the corner peripheral area PAc may be modified from the dotted line area to the solid line area.

The common voltage supply line ELVSSL may be arranged outside the internal circuit unit 40 and may surround at least a portion of the internal circuit unit 40. The internal circuit unit 40 may be arranged between the common voltage supply line ELVSSL and the display area DA.

In FIG. 5A, the first internal circuit 41 is described as the emission control driving circuit, and the second internal circuit 42 is a described as the scan driving circuit, but embodiments according to the present disclosure are not limited thereto.

As shown in FIG. 5B, the first internal circuit 41 may be the scan driving circuit, and the second internal circuit 42 may be the emission control driving circuit. That is, the scan driving circuits may be arranged in the upper area of the display panel, that is, the first peripheral area PA1, along the first direction, and the emission control driving circuits may be arranged in a shape of a corner in the corner peripheral area PAc.

In addition, the internal circuit unit 40 of FIGS. 5A and 5B may further include a previous scan driving circuit configured to provide a previous scan signal. The previous scan driving circuit and the scan driving circuit may be provided in a pair.

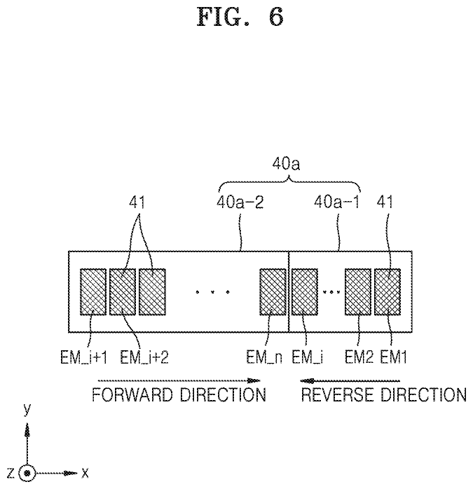

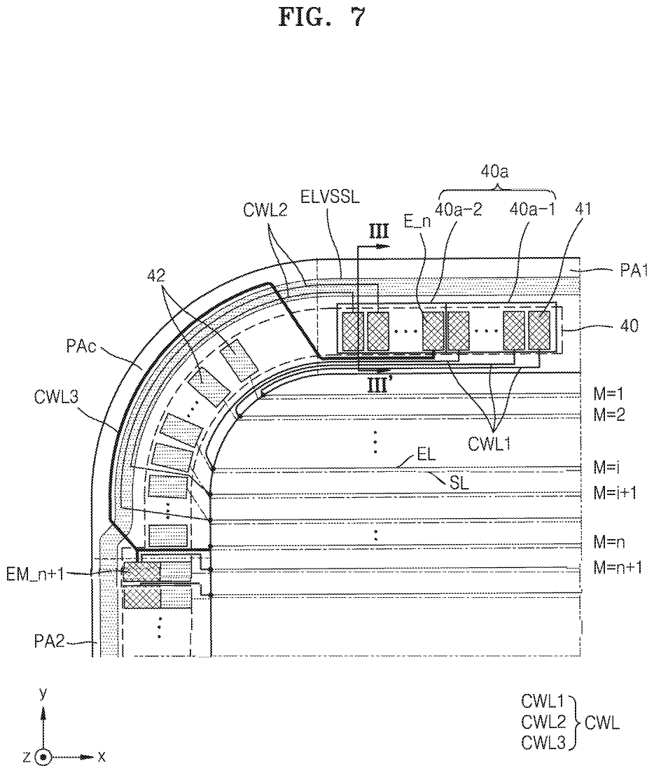

FIG. 6 shows an arrangement relationship of the internal circuits arranged in the first internal circuit unit, and FIG. 7 is a plan view schematically showing connection lines connecting the internal circuit unit of the peripheral area to the lines of the display area.

Referring to FIGS. 6 and 7, the first internal circuit unit 40a may be arranged in the first peripheral area PA1, which is the upper side of the display area DA. The plurality of first internal circuits 41 may be arranged in a line along the first direction (the x direction) in the first internal circuit unit 40a. The first internal circuits 41 may be emission control driving circuits EM1 to EMn (n is a natural number).

The first internal circuit unit 40a may include a 1-1^{st} internal circuit unit 40a-1 and a 1-2^{nd} internal circuit unit 40a-2. In the 1-1^{st} internal circuit unit 40a-1, the first internal circuits 41 configured to provide signals to the pixel circuits arranged in the first to i^{th} rows may be arranged in a reverse direction.

The first emission control driving circuit EM1 may be electrically connected to the pixel circuits arranged in a first row (M=1) in the display area DA to provide the emission control signal to the pixel circuits arranged in the first row.

The second emission control driving circuit EM2 may be electrically connected to the pixel circuits arranged in a second row (M=2) in the display area DA to provide the emission control signal to the pixel circuits arranged in the second row.

The i^{th} emission control driving circuit EM_i may be electrically connected to the pixel circuits arranged in an i^{th} row (M=i) in the display area DA to provide the emission control signal to the pixel circuits arranged in the i^{th} row (i is a natural number less than n).

According to some embodiments, the emission control driving circuits EM1 to EM_i arranged in the 1-1^{st} internal circuit unit 40a-1 may be arranged in the −x direction as row numbers of the pixel circuits configured to provide a signal increases. In the present specification, the above arrangement is defined as being arranged in the reverse direction.

In the 1-2^{nd} internal circuit unit 40a-2, the first internal circuits 41 configured to provide signals to the pixel circuits arranged in the i+1^{st} to n^{th} rows may be arranged in a reverse direction.

The i+1^{st} emission control driving circuit EM_i+1 may be electrically connected to the pixel circuits arranged in a i+1^{st} row (M=i+1) in the display area DA to provide the emission control signal to the pixel circuits arranged in the i+1^{st} row.

The i+2^{nd} emission control driving circuit EM_i+2 may be electrically connected to the pixel circuits arranged in a i+2^{nd} row (M=i+2) in the display area DA to provide the emission control signal to the pixel circuits arranged in the i+2^{nd} row.

The n^{th} emission control driving circuit EM_n may be electrically connected to the pixel circuits arranged in an n^{th} row (M=n) in the display area DA to provide the emission control signal to the pixel circuits arranged in the n^{th} row.

According to some embodiments, the emission control driving circuits EM_i+1 to EM_n arranged in the 1-2^{nd} internal circuit unit 40a-2 may be arranged in the +x direction as row numbers of the pixel circuits configured to provide a signal increases. In the present specification, the above arrangement is defined as being arranged in the forward direction.

Each of the first internal circuits 41 arranged in the first internal circuit unit 40a may be connected, through the connection lines CWL, to the signal lines, for example, the emission control lines EL, arranged in the display area DA.

The connection line CWL may include first connection lines CWL1 and second connection lines CWL2. The connection line CWL may further include third connection lines CWL3.

The first connection line CWL1 may connect the first internal circuit 41 arranged in the 1-1^{st} internal circuit unit 40a-1 with the signal line connecting the pixel circuits arranged in the same row in the display area DA. For example, the first connection line CWL1 may connect the emission control driving circuit arranged in the 1-1st internal circuit unit 40a-1 to the emission control line EL arranged in the display area DA.

The first connection line CWL1 may extend in a direction from the first internal circuit 41 to the display area DA, that is, in the −y direction. The first connection line CWL1 may be arranged in the peripheral area PA and between the internal circuit unit 40 and the display area DA, and may extend along the edge of the display area DA. The first connection line CWL1 may arranged in the same layer as the emission control line EL, or may be arranged in another layer. If the first connection line CWL1 is arranged in a layer different from the emission control line EL, the first connection line CWL1 may be connected through the contact hole.

The second connection line CWL2 may connect the first internal circuit 41 arranged in the 1-2^{nd} internal circuit unit 40a-2 with the signal line connecting the pixel circuits arranged in the same row. For example, the second connection line CWL2 may connect the emission control driving circuit arranged in the 1-2^{nd} internal circuit unit 40a-2 to the emission control line EL arranged in the display area DA.

The second connection line CWL2 may extend in a direction from the first internal circuit 41 to the edge of the substrate, that is, in the +y direction. The second connection line CWL2 may be arranged in the peripheral area PA and between the internal circuit unit 40 and the edge of the substrate, and may extend along the edge of the substrate. At least a portion of the second connection line CWL2 may overlap the common voltage supply line ELVSSL. The second connection line CWL2 may extend along the edge of the substrate, pass through spaces between the second internal circuits 42 arranged in the corner peripheral area PAc, and extend to the display area DA.

The second connection line CWL2 may arranged in the same layer as the emission control line EL, or may be arranged in another layer. If the second connection line CWL2 is arranged in a layer different from the emission control line EL, the second connection line CWL2 may be connected through the contact hole.

The third connection line CWL3 may connect the n^{th} emission control driving circuit among the first internal circuits 41 arranged in the 1-2^{nd} internal circuit unit 40a-2 with the signal line connecting the pixel circuits arranged in the n^{th} row. In addition, the third connection line CWL3 may connect the n^{th} emission control driving circuit with the n+1^{st} emission control driving circuit arranged in the second internal circuit unit 40b. The third connection line CWL3 may be arranged between the internal circuit unit 40 and the display area DA in the first peripheral area PA1, and may be arranged between the internal circuit unit 40 and the edge of the substrate in the corner peripheral area PAc.

The third connection line CWL3 may be arranged in a layer at least partially different from the first connection line CWL1 and the second connection line CWL2. The third connection line CWL3 may partially overlap the first connection line CWL1 and/or the second connection line CWL2.

The third connection line CWL3 may be longer than the first connection line CWL1 and the second connection line CWL2. The third connection line CWL3 may consist of a metal having low resistance than the first connection line CWL1 and the second connection line CWL2. The third connection line CWL3 may be wider than the first connection line CWL1 and the second connection line CWL2. Accordingly, even if the third connection line CLW3 is provided to be long, the third connection line may have a resistance value similar to those of the first connection line CWL1 and/or the second connection line CWL2.

The first to third connection lines CWL1 to CWL3 may be variously modified in ways such as being provided as one layer in the peripheral area PA or as conductive layers arranged in different layers being connected through the contact hole.

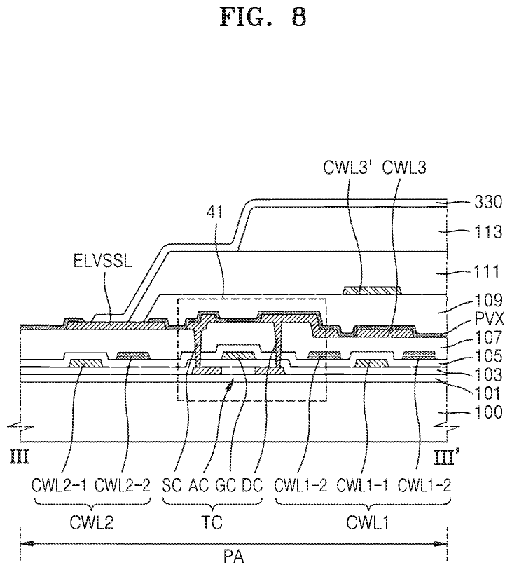

FIG. 8 is a schematic cross-sectional view of the peripheral area of the display panel taken along the line III-III′ of FIG. 7.

Referring to FIG. 8, the first internal circuit 41 is arranged in the peripheral area PA of the display panel, and the first internal circuit 41 may include at least one peripheral thin-film transistor TC.

The peripheral thin film transistor TC includes a peripheral semiconductor layer AC and a peripheral gate electrode GC. The first gate insulating layer 103 is arranged between the peripheral semiconductor layer AC and the peripheral gate electrode GC. The first gate insulating layer 103 may include inorganic insulating materials such as SiOx, SiNx, SiON, and the like. The peripheral semiconductor layer AC may be arranged in the same layer as the driving semiconductor layer A1 (see FIG. 4) and the switching semiconductor layer A2 arranged in the display area.

The semiconductor layer AC may include amorphous silicon or poly silicon. According to some embodiments, the semiconductor layer AC may include an oxide of at least one material selected from the group consisting of In, Ga, Sn, Zr, V, Hf, Cd, Ge, Cr, Ti, Al, Cs, Ce, and Zn. The peripheral semiconductor layer AC includes a peripheral channel area that is not doped with impurities and overlaps the peripheral gate electrode GC, and a peripheral source area and peripheral drain area that are doped with impurities on both sides of the peripheral channel area. The peripheral source electrode SC and the peripheral drain electrode DC may be connected to the peripheral source area and the peripheral drain area, respectively. The semiconductor layer AC may include a single layer or multiple layers.

The peripheral gate electrode GC may include Mo, Al, Cu, Ti, etc. and may include a single layer or multiple layers. For example, the peripheral gate electrode GC may be a single layer of Mo. The peripheral gate electrode GC may be arranged in the same layer as the driving and switching gate electrodes G1 and G2 and may include the same material as the driving and switching gate electrodes G1 and G2.

The peripheral gate electrode GC may be covered with the second gate insulating layer 105 and the interlayer insulating layer 107. The peripheral source electrode SC and the peripheral drain electrode DC may be arranged on the interlayer insulating layer 107, and may be connected to the peripheral semiconductor layer AC through the contact hole penetrating the interlayer insulating layer 107, the second gate insulating layer 105, and the first gate insulating layer 103. The peripheral gate electrode GC may be covered with the inorganic protective layer PVX. The first organic insulating layer 109 may be located on the inorganic protective layer PVX.

In the peripheral area PA, first connection lines CWL1 may be arranged at one side of the first internal circuit 41, and the second connection lines CWL2 may be arranged at the other side of the first internal circuit 41. The first connection lines CWL1 may be arranged at a side close to the display area, and the second connection line CWL2 may be arranged at a side close to the edge of the substrate. In addition, the third connection line CWL3 may be arranged in the peripheral area PA.

The first connection lines CWL1 may include a 1-1^{st} connection line CWL1-1 and a 1-2^{nd} connection line CWL1-2, which are arranged in different layers. The 1-1^{st} connection line CWL1-1 may be located on the first gate insulating layer 103. The 1-1^{st} connection line CWL1-1 may be arranged in the same layer as the peripheral gate electrode GC. The 1-2^{nd} connection line CWL1-2 may be located on the second gate insulating layer 105.

The second connection lines CWL2 may include a 2-1^{st} connection line CWL2-1 and a 2-2^{nd} connection line CWL2-2, which are arranged in different layers. The 2-1^{st} connection line CWL2-1 may be located on the first gate insulating layer 103. The 2-1^{st} connection line CWL2-1 may be arranged in the same layer as the peripheral gate electrode GC. The 2-2^{nd} connection line CWL2-2 may be located on the second gate insulating layer 105.

The third connection lines CWL3 and CWL3′ may be arranged at one side of the first internal circuit 41. In some embodiments, the third connection line CWL3 may be located on the interlayer insulating layer 107. According to some embodiments, the third connection line CWL3′ may be located on the first organic insulating layer 109. Alternatively, some areas of the third connection lines CWL3 and CWL3′ may be arranged in the interlayer insulating layer 107 and other areas of the third connection lines CWL3 and CWL3′ may be arranged in the first organic insulating layer 109, and thus, the two areas may be connected through the contact hole. In some embodiments, the width of each of the third connection lines CWL3 and CWL3′ maybe greater than the width of each of the first connection line CWL1 and the second connection line CWL2.

The common voltage supply line ELVSSL may be arranged in the peripheral area PA to be adjacent to the edge of the substrate 100. The first internal circuit 41 may be arranged between the display area PA and the common voltage supply line ELVSSL. The common voltage supply line ELVSSL may be provided with the same material in the same layer as the data line DL, the driving voltage line PL, the source electrodes S1, S2, and SC, or the drain electrodes D1, D2, and DC. The common voltage supply line ELVSSL may include a conductive material including Mo, Al, Cu, Ti, etc., and may include a single layer or multiple layers including the above material. For example, the common voltage supply line ELVSSL may have a multilayer structure of Ti/Al/Ti.

The common voltage supply line ELVSSL may be connected to the opposite electrode 330 and be configured to transmit a common power supply voltage ELVSS to the opposite electrode 330. The opposite electrode 330 may be integrally provided in a plurality of pixels, thereby connecting an end of the opposite electrode 330 to the common voltage supply line ELVSSL. In the drawings, although the opposite electrode 330 is shown to be in direct contact with the common voltage supply line ELVSSL, embodiments are not limited thereto. For example, the conductive layer is provided between the opposite electrode 330 and the common voltage supply line ELVSSL, and thus, the opposite electrode 330 may be connected to the common voltage supply line ELVSSL through the conductive layer.

The common voltage supply line ELVSSL may at least partially overlap the second connection lines CWL2. Accordingly, a dead space of the peripheral area PA may be reduced.

In addition, in the peripheral area PA, the second organic insulating layer 111 may be arranged to cover a side surface of the first organic insulating layer 109. However, the disclosure is not limited thereto. The second organic insulating layer 111 may be arranged only on the top of the first organic insulating layer 109, so that the first organic insulating layer 109 and the second organic insulating layer 111 are provided in the form of a staircase at the end.

In the display panel according to some embodiments, an internal circuit unit may be arranged on top of the display panel, wherein some of the internal circuits included in the internal circuit unit are arranged in a reverse direction and some of the others are arranged in a forward direction. Accordingly, a high-quality image may be implemented, and, at the same time, the dead space of the corner peripheral area may be reduced. In addition, the connection line connected to the internal circuit unit may be evenly arranged on one side and the other side of the internal circuit unit, which may further reduce the dead space of the peripheral area.

Embodiments that may be applied to the embodiments of the disclosure have been described. Such embodiments may be implemented as separate embodiments or embodiments combined with one another. For example, a variety of combinations are possible, such as applying the embodiments described as examples in FIGS. 6 to 8 to the embodiments described as an example in FIG. 5B.

As described above, one or more embodiments are described with reference to the embodiments shown in the drawings, which are merely examples, and those skilled in the art will understand that various modifications and equivalent other embodiments are possible therefrom. Therefore, the true technical protection scope of the present disclosure should be determined by the technical spirit of the appended claims.

According to the embodiments, the display panel may include the internal circuit unit on top of the display panel, wherein some of the internal circuits included in the internal circuit unit are arranged in a reverse direction and some of the others are arranged in a forward direction, thereby enabling the display panel to provide a relatively a high-quality image and the area of the peripheral area may be relatively reduced at the same time. However, the scope of embodiments according to the present disclosure are not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A display panel comprising:
a substrate comprising a display area and a peripheral area surrounding the display area;
first signal lines on the substrate and extending in a first direction;
data lines on the substrate and extending in a second direction crossing the first direction;
pixel circuits arranged in a matrix along the first direction and the second direction and display elements respectively connected to the pixel circuits, the pixel circuits and the display elements being in the display area;
a first internal circuit unit comprising first internal circuits arranged along the first direction in the peripheral area; and
connection lines arranged in the peripheral area to connect each of the first internal circuits to each of the first signal lines, wherein
the first internal circuit unit comprises a 1-1^{st} internal circuit unit in which the first internal circuits configured to provide signals to the pixel circuits arranged in the first to i^{th} rows are arranged in a reverse direction to the first direction, and a 1-2^{nd} internal circuit unit in which the first internal circuits configured to provide signals to the pixel circuits arranged in the i+1^{st} to n^{th} rows are arranged in the first direction, and i and n are natural numbers.

2. The display panel of claim 1, wherein the connection lines comprise first connection lines between the first internal circuit unit and the display area, and second connection lines between the first internal circuit unit and an edge of the substrate.

3. The display panel of claim 1, further comprising a common voltage power source line in the peripheral area and surrounding at least a portion of the display area, wherein
at least some of the connection lines overlap the common voltage power source line.

4. The display panel of claim 1, wherein
the peripheral area comprises a first peripheral area outside a first side of the display area, a second peripheral area outside a second side of the display area, and a corner peripheral area outside a corner at which the first side and the second side meet,
a corner internal circuit unit in the corner peripheral area, wherein the corner internal circuit unit is configured to provide a signal that is different from that of the first internal circuit unit to the pixel circuits.

5. The display panel of claim 4, wherein the corner internal circuit unit comprises second internal circuits configured to provide a signal different from that of the first internal circuits.

6. The display panel of claim 5, wherein the first internal circuits are emission control driving circuits, and the second internal circuits are scan driving circuits.

7. The display panel of claim 5, wherein the second internal circuits are arranged radially according to a shape of the corner peripheral area.

8. The display panel of claim 5, wherein some of the connection lines are between the second internal circuits.

9. The display panel of claim 4, wherein a scan driving circuit and an emission control driving circuit are arranged in a pair in the second peripheral area.

10. The display panel of claim 4, wherein
a second internal circuit unit is in the second peripheral area, and
a third connection line among the connection lines connects the first internal circuit unit and the second internal circuit unit.

11. The display panel of claim 10, wherein a portion of the third connection line is between the first internal circuit unit and the display area, and another portion is between the corner internal circuit unit and an edge of the substrate.

12. A display panel comprising:
a substrate comprising a display area and a peripheral area surrounding the display area;
first signal lines on the substrate and extending in a first direction;
data lines on the substrate and extending in a second direction crossing the first direction;
pixel circuits arranged in a matrix along the first direction and the second direction and display elements respectively connected to the pixel circuits, the pixel circuits and the display elements being arranged in the display area;
a first internal circuit unit comprising first internal circuits arranged along the first direction in the peripheral area;
connection lines in the peripheral area to connect each of the first internal circuits to each of the first signal lines; and
a common voltage supply line in the peripheral area between the first internal circuit unit and an edge of the substrate, wherein at least some of the connection lines overlap the common voltage supply line.

13. The display panel of claim 12, wherein the connection lines comprise first connection lines and second connection lines, the first connection lines and the second connection lines extending from the first internal circuit unit in different directions from each other.

14. The display panel of claim 13, wherein the first connection lines are between the first internal circuit unit and the display area, and second connection lines are between the first internal circuit unit and the edge of the substrate.

15. The display panel of claim 12, wherein
the peripheral area comprises a first peripheral area outside a first side of the display area, a second peripheral area outside a second side of the display area, and a corner peripheral area outside a corner at which the first side and the second side meet,
a corner internal circuit unit is in the corner peripheral area, wherein the corner internal circuit unit is configured to provide a signal different from that of the first internal circuit unit to the pixel circuits.

16. The display panel of claim 15, wherein the corner internal circuit unit comprises second internal circuits.

17. The display panel of claim 16, wherein the first internal circuits are emission control driving circuits, and the second internal circuits are scan driving circuits.

18. The display panel of claim 16, wherein the second internal circuits are arranged radially according to a shape of the corner peripheral area.

19. The display panel of claim 16, wherein some of the connection lines are between the second internal circuits.

20. The display panel of claim 15, wherein
a second internal circuit unit is in the second peripheral area, and
a third connection line among the connection lines connects the first internal circuit unit and the second internal circuit unit.
